(19) United States
(12) Patent Application Publication
(10) Pub. No.: US 2017/0263799 A1
(43) Pub. Date: Sep. 14, 2017

(54) ACTIVE BLUE LIGHT LEAKAGE PREVENTING LED STRUCTURES

(71) Applicant: NATIONAL CENTRAL UNIVERSITY, Taoyuan (TW)

(72) Inventors: Ching-Cherng SUN, Taoyuan (TW); Tsung-Hsun YANG, Taoyuan (TW)

(73) Assignee: National Central University

(21) Appl. No.: 15/167,455

(22) Filed: May 27, 2016

(30) Foreign Application Priority Data
Mar. 8, 2016 (TW) TW105107096

(51) Int. Cl. H01L 31/173; H01L 21/66; H01L 33/58; H01L 33/48; H01L 33/50

(52) U.S. Cl. CPC H01L 31/173; H01L 33/483; H01L 33/502; H01L 33/58; H01L 22/20; H01L 22/30

(57) ABSTRACT

The present invention discloses active blue light leakage preventing LED structures. Each of the structure includes a circuit board, at least one blue light LED die, a photo detector and a wavelength transformation layer, wherein the electric circuit on the circuit board receives detection signal from the photo detector and turns off the said blue light LED die accordingly. With the implementation of the present invention, the active blue light leakage preventing LED structure turns off the blue light LED die when it reaches its usage life span limit thus avoiding damage to human from the massive release of blue light.

### BACKGROUND OF THE INVENTION

1. Technical Field

The present invention relates to LED structures and, more particularly, to active blue light leakage preventing LED structures.

2. Description of Related Art

The earth is more and more consumed and damaged by people when the progress of living keeps advancing. Hence comes the need for the everlasting existence of the earth with the increasing demands for energy saving and environmental protection solution. Out of those demands, light-emitting diodes (LEDs) advantageously feature small physical volume, high brightness, low power consumption, and ease of use and replacement and become the most rapidly growing application.

Wherein the life span or life limit of LED, known as L70, is commonly defined as the light emitted by a LED reduces to about 70% of its stable emission value. However, in actual applications, the luminous efficiency of most white light LEDs will reduce even before L70 is reached due to the heat generated that the absorption and transformation of the fluorescent material decrease accordingly. The reduction in luminous efficiency then generates more heat. With such cycling mutual effect of heat and efficiency reduction keep going on and on, massive blue light is then inevitably leaked.

On the other hand, with the increasing usage of LEDs, more and more researches and papers about the destructive effect of blue light to human eyes are published to warn that irreversible damages will occur while human eyes are exposed to blue light for more than certain amount or for certain duration.

In view of the above, it has been a common goal and progress of the LED industries and the lighting industries to create a practical, effective and easy-to-use lighting LED structure that can rapidly, accurately and actively detect abnormal status and turn off the white light LED before massive heat is generated and great amount of blue light is emitted, and thus the protection of human eyes and life quality are thus desirably achieved, while at the same time informing the user the need of replacement of lighting device.

### BRIEF SUMMARY OF THE INVENTION

The present invention discloses active blue light leakage preventing LED structures. Each of the structure includes a circuit board, at least one blue light LED die, a photo detector and a wavelength transformation layer, wherein the electric circuit on the circuit board receives detection signal from the photo detector and turns off the said at least one blue light LED accordingly. With the implementation of the present invention, the active blue light leakage preventing LED structure turns off the white light LED when it reaches its usage life span limit thus avoiding the damage to human from the massive release of blue light.

The present invention provides an active blue light leakage preventing LED structure, comprising: a circuit board, comprising an upper surface; at least one blue light LED die, provided on the said upper surface and electrically connected to the said circuit board; a photo detector, provided on the said upper surface and electrically connected to the said circuit board, detecting a back scattering light of a wavelength transformation layer which results from the said blue light LED die and generating a detection signal; and a wavelength transformation layer, provided on the said upper surface, covering the said blue light LED die and the said photo detector; wherein the circuit of the said circuit board detects the said detection signal and turns off the said blue light LED die accordingly.

The present invention further provides an active blue light leakage preventing LED structure, comprising: a circuit board, comprising an upper surface; at least one blue light LED die, provided on the said upper surface and electrically connected to the said circuit board; a photo detector, provided on the said upper surface and electrically connected to the said circuit board, detecting a back scattering light of a wavelength transformation layer which results from the said blue light LED die and generating a detection signal; and a wavelength transformation layer, provided and covering a light emitting surface of the said blue light LED die; wherein the circuit of the said circuit board detects the said detection signal and turns off the said blue light LED die accordingly.

Implementation of the present invention at least involves the following inventive steps:

1. The need of complicated process or complicated equipment is not required, thus reduces implementation cost.

2. Capable of turning off the blue light LED die in time to prevent massive leakage of blue light to endanger an user.

3. Actively turn off blue light LED die to inform the user the need of replacement of lighting device, enables applications of smart controls.

The features and advantages of the present invention are detailed hereinafter with reference to the preferred embodiments. The detailed description is intended to enable a person skilled in the art to gain insight into the technical contents disclosed herein and implement the present invention accordingly. In particular, a person skilled in the art can easily understand the objects and advantages of the present invention by referring to the disclosure of the specification, the claims, and the accompanying drawings.

### BRIEF DESCRIPTION OF THE SEVERAL VIEWS OF THE DRAWINGS

The invention as well as a preferred mode of use, further objectives and advantages thereof will be best understood by reference to the following detailed description of illustrative embodiments when read in conjunction with the accompanying drawings, wherein:

FIG. 1 is a sectional plan view of the active blue light leakage preventing LED structure according to an embodiment of the present invention;

FIG. 2 is a sectional plan view of the active blue light leakage preventing LED structure according to another embodiment of the present invention;

FIG. 3 is a sectional plan view of the active blue light leakage preventing LED structure according to the embodiment of FIG. 1 further comprises a packaging lens; and

FIG. 4 is a sectional plan view of the active blue light leakage preventing LED structure according to the embodiment of FIG. 2 further comprises a packaging lens.

### DETAILED DESCRIPTION OF THE INVENTION

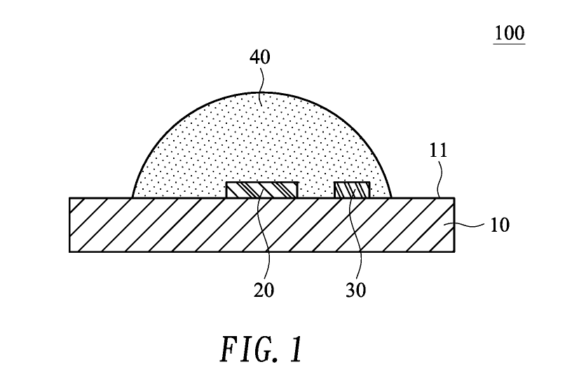

Please refer to FIG. 1, an active blue light leakage preventing LED structure 100 according to an embodiment of the present invention includes a circuit board 10, at least one blue light LED die 20, a photo detector 30, and a wavelength transformation layer 40.

As shown in FIG. 1, the circuit board 10 of the active blue light leakage preventing LED structure 100 comprises an upper surface 11, and the circuit board 10 can be a FRP, ceramic, or flexible circuit board that contains at least one set of circuit path.

As also shown in FIG. 1, at least one blue light LED die 20 is provided on an upper surface 11 of the circuit board 10 and is electrically connected to the circuit board 10. The number or size or even the specification or grade of the said blue light LED die 20 that emits blue light can be chosen as required in actual applications.

Referring again to FIG. 1, the photo detector 30 is also provided on the upper surface 11 of the circuit board 10 and is electrically connected to the circuit board 10. In the embodiment, the photo detector 30 is to detect a back scattering light of a wavelength transformation layer 40 which results from the said blue light LED die 20 and then generates a detection signal for control usage. Wherein the circuit board 10 or at least one set of circuit path of the circuit board 10 receives the detection signal generated from the photo detector 30 and turns off the blue light LED die 20 accordingly.

With continued reference to FIG. 1, the wavelength transformation layer 40, which is provided and set also on the upper surface 11 of the circuit board 10, covers the blue light LED die 20 and the photo detector 30. The said wavelength transformation layer 40 can be a phosphor powder layer, a quantum dot layer, or any material layer formed with photoluminescence material.

Further, the phosphor powder layer used as the wavelength transformation layer 40 can be a yellow color phosphor powder layer, a red-green mixed color phosphor powder layer, or an orange-green mixed color phosphor powder layer.

The aforesaid back scattering light received by the photo detector 30 is a portion of the blue light emitted by the blue light LED die 20 and reflected by the wavelength transformation layer 40 toward the photo detector 30.

When the detected back scattering light reduces to a value below a predetermined threshold after a period of time of usage, the active blue light leakage preventing LED structure 100 is about to radiate large amount of blue light, wherein the temperature of the wavelength transformation layer 40 is greatly raised thus reduces enormously the light mixing function to leak massive quantity of blue light.

With the implementation of the photo detector 30 on the upper surface 11 of the circuit board 10, the back scattering light inside the active blue light leakage preventing LED structure 100 can always be detected, thus, the photo detector 30 actively generates a detection signal for the electrical circuit on the circuit board 10 to turn off the blue light LED die 20 accordingly, preventing unnecessary damage to users.

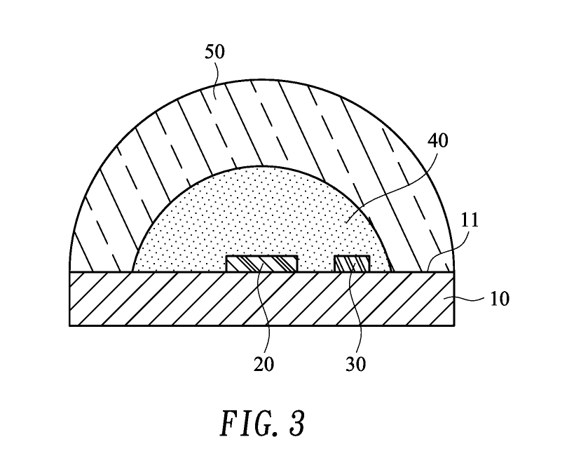

As shown in FIG. 3, the active blue light leakage preventing LED structure 100 further comprises a packaging lens 50, provided and featured on the upper surface 11 of the circuit board 10 to cover the wavelength transformation layer 40, the photo detector 30, and the blue light LED die 20.

Wherein the said packaging lens 50 or the said wavelength transformation layer 40 can be glued on the upper surface 11 of the circuit board 10 with a gasket.

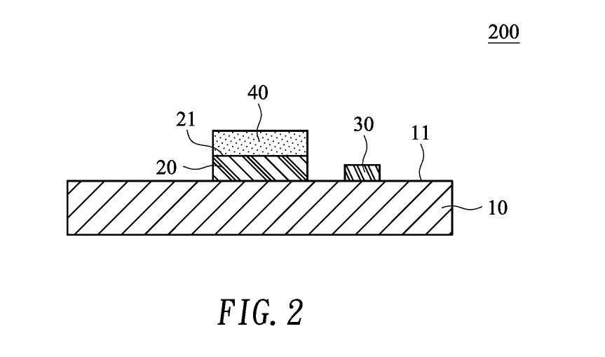

Please refer to FIG. 2, an active blue light leakage preventing LED structure 200 according to another embodiment of the present invention includes a circuit board 10, at least one blue light LED die 20, a photo detector 30, and a wavelength transformation layer 40.

As shown in FIG. 2, the wavelength transformation layer 40 of the embodiment covers only the light emitting surface 21 of the blue light LED die 20.

In this embodiment, the features and the relationships of the circuit board 10, the blue light LED die 20 and the photo detector 30 of the active blue light leakage preventing LED structure 200 are the same as in the embodiment of the active blue light leakage preventing LED structure 100 that requires no further descriptions.

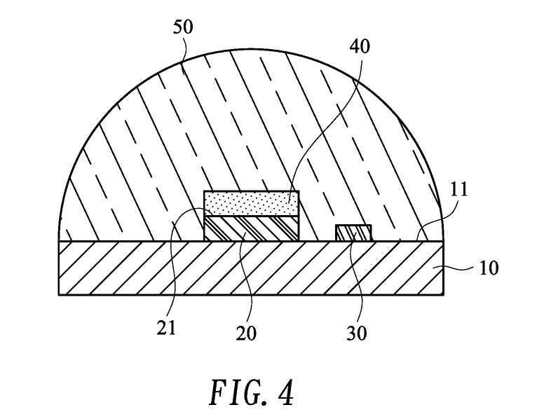

As shown in FIG. 4, the active blue light leakage preventing LED structure 200 further comprises a packaging lens 50, provided and fixed on the upper surface 11 of the circuit board 10 to cover the wavelength transformation layer 40, the photo detector 30, and the blue light LED die 20.

As can be seen in FIG. 3 and FIG. 4, the implementation of the packaging lens 50 not only protects the wavelength transformation layer 40, the photo detector 30, and the blue light LED die 20 covered, also the beam shape, the focus point, the beam size or the beam divergence angle of the active blue light leakage preventing LED structure 100 or the active blue light leakage preventing LED structure 200 can be achieved by choosing different shape or function of the packaging lens 50.

Moreover, with the implementation of the photo detector 30 on the upper surface 11 of the circuit board 10, the active blue light leakage preventing LED structure 200 is also capable of detecting the back scattering light of the wavelength transformation layer which results from the blue light LED die 20 inside. When the blue light LED die 20 reaches its usage life span limit, the detected back scattering blue light reduces to a value below a predetermined threshold after a period of time of usage and the active blue light leakage preventing LED structure 100 is about to radiate large amount of blue light, wherein the temperature of the wavelength transformation layer 40 is greatly raised thus reduces enormously the light mixing function to leak massive quantity of blue light, the photo detector 30 actively generates a detection signal for the electrical circuit on the circuit board 10 to turn off the blue light LED die 20 accordingly, thus preventing unnecessary damage to an user.

That is to say, with the photo detector 30 implemented inside, both the active blue light leakage preventing LED structure 100 and the active blue light leakage preventing LED structure 200 are embodiments achieving the specific features or the inventive steps as stated above, wherein the active blue light leakage preventing LED structure 100 or the active blue light leakage preventing LED structure 200 can be a white light LED structure.

The embodiments described above are intended only to demonstrate the technical concept and features of the present invention so as to enable a person skilled in the art to understand and implement the contents disclosed herein. It is understood that the disclosed embodiments are not to limit the scope of the present invention. Therefore, all equivalent changes or modifications based on the concept of the present invention should be encompassed by the appended claims.

1-5. (canceled)

6. An active blue light leakage preventing LED structure, comprising:
a circuit board having an upper surface;
at least one blue light LED die provided on the upper surface and electrically connected to the circuit board;
a photo detector provided on the upper surface and electrically connected to the circuit board, configured to detect a back scattering light of the blue light LED die and to generate a detection signal; and
a wavelength transformation layer formed to cover at least a light emitting surface of the blue light LED die,
wherein the circuit of the circuit board is configured to detect the detection signal and turn off the blue light LED die accordingly.

7. The active blue light leakage preventing LED structure of claim 6, wherein the wavelength transformation layer is phosphor powder layer, a quantum dot layer, or any material layer formed with photoluminescence material.

8. The active blue light leakage preventing LED structure of claim 6, wherein the wavelength transformation layer is a yellow color phosphor powder layer, a red-green mixed color phosphor powder layer, or an orange-green mixed color phosphor powder layer.

9. The active blue light leakage preventing LED structure of claim 6, wherein the photo detector is configured to detect a back scattering light generated from the blue light LED die and reflected from the wavelength transformation layer.

10. The active blue light leakage preventing LED structure of claim 6, further comprising a packaging lens provided on the upper surface and covering the blue light LED die, the photo detector and the wavelength transformation layer.

11. The active blue light leakage preventing LED structure of claim 6, wherein the wavelength transformation layer is further formed on the upper surface to cover the blue light LED die and the photo detector.

12. The active blue light leakage preventing LED structure of claim 11, further comprising a packaging lens provided on the upper surface and covering the blue light LED die, the photo detector and the wavelength transformation layer.
